(19) United States
(12) Patent Application Publication
(10) Pub. No.: US 2016/0155958 A1
(43) Pub. Date: Jun. 2, 2016

(54) BICYCLIC IRIDIUM COMPLEX AND PROCESS FOR PREPARING SAME, ORGANIC LIGHT EMITTING DEVICE AND PROCESS FOR PREPARING SAME

(71) Applicants: HEFEI BOE OPTOELECTRONICS TECHNOLOGY CO., LTD., Hefei, Anhui (CN); BOE TECHNOLOGY GROUP CO., LTD., Beijing (CN)

(72) Inventors: YUANHUI GUO, Beijing (CN); HUI WANG, Beijing (CN); XIN YE, Beijing (CN); FENG QIN, Beijing (CN)

(21) Appl. No.: 14/344,796

(22) PCT Filed: May 28, 2013
(86) PCT No.: PCT/CN2013/076301

§ 371 Date: Mar. 13, 2014

(30) Foreign Application Priority Data
Feb. 7, 2013 (CN) 201310049626.7

(51) Int. Cl. H01L 51/00; C09K 11/06; C09K 11/02; C07F 15/00

(52) U.S. Cl. CPC H01L 51/0085; C07F 15/0033; C09K 11/06; H01L 51/0042; H01L 51/007; C09K 11/02; H01L 51/5012

(57) ABSTRACT

The invention provides a bicyclic iridium complex and a process for preparing the same, an organic light emitting device and a process for preparing the same, and belongs to the art of organic light emitting. The light emitting layer of the organic light emitting device comprises a bicyclic iridium complex, which has the following structure, wherein the substituents R₁ and R₂ are the same or different. The organic light emitting device of the invention has a high external quantum efficiency, a high saturation of red light emission, and stable light emitting performance.

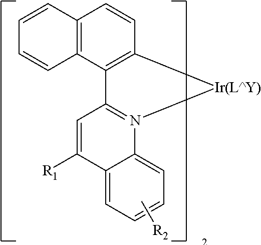

### TECHNICAL FIELD

The invention relates to a bicyclic iridium complex and a process for preparing the same, an organic light emitting device and a process for preparing the same.

### BACKGROUND

In the prior art, the following displays are primarily used in practice: cathode ray tube (CRT), liquid crystal display (LCD), vacuum fluorescent display (VFD), plasma display panel (PDP), organic light emitting device (OLED), field emission display (FED), electroluminescent display (ELD) and the like.

As a novel flat panel display, OLED has the advantages of being thin, light, having wide visual angle, being active light emitting, emitting continuously adjustable color, having low cost, rapid response, low energy consumption, low driving voltage, wide range of working temperature, simple manufacturing process, high light emitting efficiency, flexible display, and the like, as compared to LCD. Due to its advantages that cannot be matched by other displays and its great prospect of application, OLED attracts great focus from the industry and academic circles.

To achieve practical application and industrialization of the organic light emitting device, one key factor is to improve the light emitting efficiency and brightness. The improvement of the efficiency and brightness is dependent on not only the performance of the designed device, but also a high performance red light emitting. This is because to satisfy the application of all color display and illumination, among the three primary colors, the red light is indispensible. However, as compared to high performance green light emitting devices, currently the studies on red light emitting devices lag behind. The reasons that cause such situation include: (1) compounds corresponding to red light emission have low energy level differences, and this poses certain difficulty to the design of a red light material ligand; (2) in a red light material system, there is strong π-π bond interaction or strong charge transfer property, which both reinforce the aggregation of molecules which easily causes quenching. Therefore, it has become a problem begging for quick fix to prepare a high performance red light emitting device.

### SUMMARY

The technical problem to be solved by the invention is to provide a bicyclic iridium complex and a process for preparing the same, an organic light emitting device and a process for preparing the same. The organic light emitting device has a high external quantum efficiency, a high red light emitting saturation level, and stable light emitting performance.

The technical problem to be solved by the invention is to provide a bicyclic iridium complex and a process for preparing the same, an organic light emitting device and a process for preparing the same, said organic light emitting device has a high external quantum efficiency, a high saturation of red light emission, and stable light emitting performance.

In order to solve the aforesaid technical problem, aspects of the invention provide the following technical solutions:

In one aspect, a bicyclic iridium complex is provided which has the following structural formula:

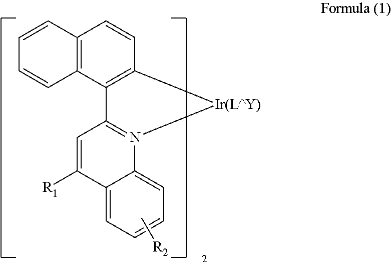

wherein R₁ and R₂ are the same or different substituents. Further, in the aforesaid solution, the substituents R₁ and R₂ are each independently selected from one of hydrogen, halogen, cyano, nitro, acyl, linear, branched or cyclic aliphatic group of 1 to 18 carbon atoms, substituted alkyl, alkyloxy, aryloxy, alkylthiol, arylthiol, aliphatic amino, aromatic amino, substituted silyloxy, substituted silyl, aryl, substituted aryl, heteroaryl and substituted heteroaryl;

preferably, the substituents R₁ and R₂ are each independently selected from hydrogen, halogen, cyano, nitro, linear or branched alkyl of 1 to 5 carbon atoms, and phenyl, furyl, thienyl, pyrrolyl, pyridyl, quinolyl, indolyl, carbazyl, acridone group, phenothiazinyl or acridinyl substituted by linear or branched alkyl of 1 to 5 carbon atoms.

L̂Y is a ligand selected from N—COOHs, 8-hydroxyquinolines, β-diones and N̂NH.

In a specific aspect, the invention provides a bicyclic iridium complex having the following structural formula:

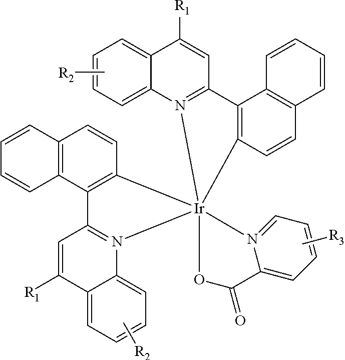

wherein R₁ and R₂ are defined as in Formula (1).

R₃ is defined similar to substituents R₁ and R₂, and can be selected from one of hydrogen, halogen, cyano, nitro, acyl, linear, branched or cyclic aliphatic group of 1 to 18 carbon atoms, substituted alkyl, alkyloxy, aryloxy, alkylthiol, arylthiol, aliphatic amino, aromatic amino, substituted silyloxy, substituted silyl, aryl, substituted aryl, heteroaryl and substituted heteroaryl.

In particular, the heteroaryl can be furyl, thienyl, pyrrolyl, pyridyl, quinolyl, indolyl, carbazyl, acridone group, phenothiazinyl or acridinyl.

Further, in the aforesaid solution, the bicyclic iridium complex preferably has the following structural formula (abbreviation of the molecular formula structure is (NPQ)₂Ir(pic)):

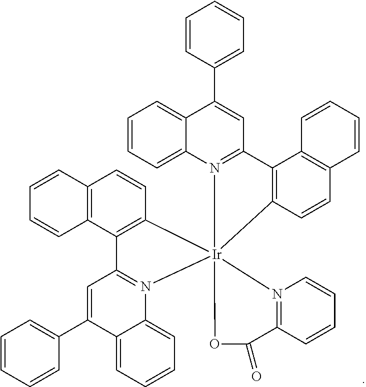

Another aspect of the invention further provides an organic light emitting device, whose light emitting layer comprises the aforesaid bicyclic iridium complex.

Further, the light emitting layer is a mixture of polyvinyl carbozole (PVK) and (NPQ)₂Ir(pic).

Further, the light emitting layer includes a host material and a guest material, wherein the host material comprises PVK and 2-(4′-t-butylphenyl)-5-(4″-biphenylyl)-1,3,4-oxidiazole (PBD), the guest material comprises (NPQ)₂Ir(pic).

Further, in the aforesaid solution, the weight ratio of (NPQ)₂Ir(pic) to the light emitting layer can be 1%-8%, preferably 1.5%-7%.

Further, in the aforesaid solution, the weight ratio of (NPQ)₂Ir(pic) to the light emitting layer can be 1.5%-5%, preferably 2%-4%.

Further, in the aforesaid solution, the organic light emitting device may include:

a substrate;

an anode disposed on the substrate;

a hole transport layer disposed on the anode;

a light emitting layer disposed on the hole transport layer;

an electron transport layer disposed on the light emitting layer;

an electron injection layer disposed on the electron transport layer; and

a cathode disposed on the electron injection layer.

Further, in the aforesaid solution, the thickness of the light emitting layer does not exceed 100 nm, preferably 40 nm˜100 nm.

Another aspect of the invention further provide the process for preparing the bicyclic iridium complex mentioned previously which include the following steps:

Step (1), phosphorus pentoxide is dissolved in m-cresol, to which 1-naphthalen-1-yl-ethylketone and the o-aminobenzaldehyde derivative of Formula (2) are further added for dehydration, resulting in the 2-naphthalen-1-yl quinoline derivative as shown in Formula (3);

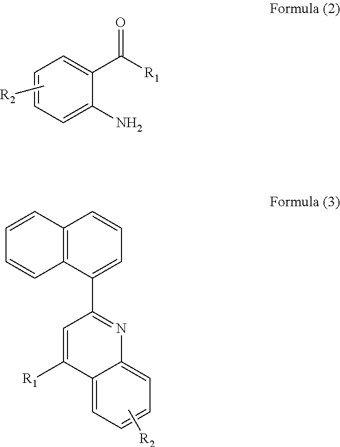

wherein substituents R₁ and R₂ are defined as the same as in Claim 1.

Step (2), IrCl₃.3H₂O is dissolved in water, to which a 2-naphthalen-1-yl quinoline derivative and a first organic solvent are added, followed by agitation in the dark under a N₂ environment, resulting in a bichloro bridge compound of iridium as shown in Formula (4);

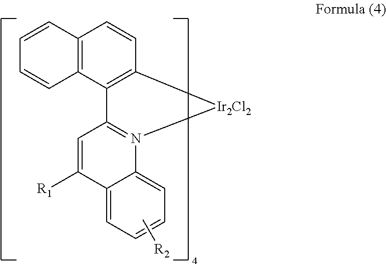

Step (3), the bichloro bridge compound of iridium is dissolved in a second organic solvent, and is agitated with an adjuvant ligand under the action of an alkali, resulting in the bicyclic iridium complex of the present disclosure. Further, in the aforesaid solution,

In Step (1), preferably, the ratio of the amounts of phosphorus pentoxide, m-cresol, 1-naphthalen-1-yl-ethylketone and the o-amino benzaldehyde derivative is roughly: 1:(10˜80):1:1, and the duration of dehydration is 4-24 h;

In Step (2), preferably, the ratio of the amounts of IrCl₃.3H₂O, the 2-naphthalen-1-yl quinoline derivative and the first organic solution is roughly: 1:(2˜5):(50˜300), and the agitation in the dark is conducted at temperature of 50˜200° C. and N₂ environment for 8˜48 h;

In Step (3), preferably, the dichloro bridge compound of iridium, the second organic solution, the alkali and the adjuvant ligand are used in a rough ratio of 1:(10˜500):(1˜5):(1˜5), and the agitation is conducted with the adjuvant ligand under the action of the alkali at 20˜200° C. for 3˜48 h.

Further, in the aforesaid solution, the first organic solvent can be selected from ethylene glycol ethyl ether, glycidyl ether and glycerol;

the second organic solvent can be selected from one or more of dichloromethane, ethylene glycol ethyl ether, glycerol and glycidyl ether;

the alkali can be selected from potassium carbonate, potassium bicarbonate, sodium carbonate, sodium bicarbonate, sodium hydroxide, potassium hydroxide, triethylamine or pyridine;

Yet another aspect of the invention further provide a process for preparing an organic light emitting device, which process comprises preparing the light emitting layer of the organic light emitting device using the aforesaid bicyclic iridium complex.

Further, in the aforesaid solution, the process for preparation specifically comprises:

conducting vacuum evaporation or spin coating on the hole transport layer with a mixture of the bicyclic iridium complex and PVK, forming the light emitting layer.

Aspects of the invention have the following advantageous effect:

in the aforesaid solution, the light emitting layer of the organic light emitting device employs a mixture of bicyclic iridium complex and PVK, the organic light emitting device employs said light emitting layer has a high external quantum efficiency, a high saturation of red light emission, as well as a stable light emitting performance upon change of electric current.

### BRIEF DESCRIPTION OF THE DRAWINGS

FIG. 1 is the schematic structural diagram of organic light emitting device of the invention.

FIG. 2 is the schematic flow chart of the process for preparing the organic light emitting device of the invention;

FIG. 3 is the current density-voltage-brightness plot for the organic light emitting device prepared in Example 1 of the invention.

FIG. 4 is the light emitting spectrum of the organic light emitting device prepared in Example 2 of the invention under different current density.

FIG. 5 is the current density-external quantum efficiency plot of the organic light emitting device prepared in Example 3 of the invention.

FIG. 6 is the light emitting spectrum of the organic light emitting device prepared in Example 4 of the invention.

### DETAILED DESCRIPTION

In order to make the technical problem to be solved, technical solutions and advantages of the invention clearer, they are described in details below in reference to the figures and specific examples.

Facing the current problem of low performance of the red light emitting device, the invention provides a bicyclic iridium complex and a process for preparing the same, an organic light emitting device and a process for preparing the same. The organic light emitting device has a high external quantum efficiency, a high saturation of red light emission, and stable light emitting performance.

A preferred embodiment of the invention provides a bicyclic iridium complex is provided which has the following structural formula:

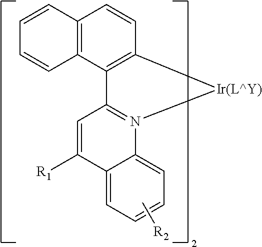

wherein substituents R₁ and R₂ are the same or different.

Further, the substituents R₁ and R₂ can be each independently selected from one of hydrogen, halogen, cyano, nitro, acyl, linear, branched or cyclic aliphatic group of 1 to 18 carbon atoms, substituted alkyl, alkyloxy, aryloxy, alkylthiol, arylthiol, aliphatic amino, aromatic amino, substituted silyloxy, substituted silyl, aryl, substituted aryl, heteroaryl and substituted heteroaryl, the heteroaryl being furyl, thienyl, pyrrolyl, pyridyl, quinolyl, indolyl, carbazyl, acridone group, phenothiazinyl, or acridinyl;

preferably, the substituents R₁ and R₂ are the same;

preferably, the substituents R₁, R₂ are each independently selected from hydrogen, halogen, cyano, nitro, linear or branched alkyl of 1 to 5 carbon atoms, and phenyl, furyl, thienyl, pyrrolyl, pyridyl, quinolyl, indolyl, carbazyl, acridone group, phenothiazinyl or acridinyl substituted by linear or branched alkyl of 1 to 5 carbon atoms.

Preferably, the substituents R₁, R₂ can be aryl or substituted aryl, such as phenyl.

L̂Y can be selected one of from N—COOHs, 8-hydroxyquinolines, β-diones and N̂NH.

N—COOH ligands indicate the following: in N—COOH ligands, N indicates a moiety of a nitrogen-containing group(such as 5-membered azacarbocycle, 6-membered azacarbocycle), and —COOH indicates a carboxylic moiety linked to a non-nitrogen atom on the nitrogen-containing moiety. When the N—COOH ligand forms a coordination with the Ir atom, the nitrogen atom in the nitrogen-containing group and the oxygen on the hydroxy part of the carboxylic group each form coordinate bonds with the Ir atom.

Examples of N—COOH ligands include heteroaryl substituted by carboxylic group, such as 2-picolinic acid.

8-hydroxyquinoline ligands, for example, include 8-hydroxyquinoline and derivatives thereof with further substitution. When an 8-hydroxyquinoline ligand forms a coordination with the Ir atom, the oxygen from hydroxy part and the nitrogen from the quinoline moiety each form coordinate bonds with the Ir atom.

β-dione ligands include all possible compounds having β-dione in their structure, such as alkanoyl acetone. When a β-dione ligand forms a coordination with the Ir atom, the oxygens from the two carbonyl groups each form coordinate bonds with the Ir atom.

N̂NH ligands comprise two nitrogen-containing moieties linked to each other, which can be the same or different. When said N̂NH ligand forms a coordination with the Ir atom, the nitrogen atoms in the two nitrogen-containing moieties each form coordinate bonds with the Ir atom.

A skilled artisan can understand that when a coordinate bond is formed, a participating atom such as nitrogen or oxygen may lose the hydrogen linked to it previously.

Preferably, L̂Y can be an N—COOH, for example the substituent below:

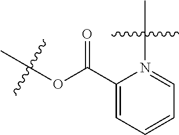

In a preferred embodiment, the invention provides a bicyclic iridium complex having the following structural formula:

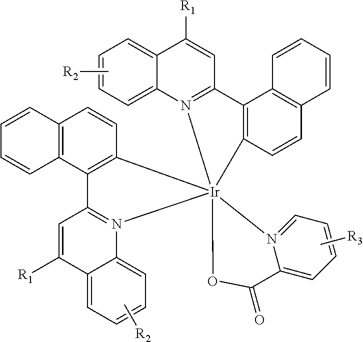

wherein R₁ and R₂ are defined as in Formula (1).

R₃ is defined similar to substituents R₁ and R₂, and can be selected from one of hydrogen, halogen, cyano, nitro, acyl, linear, branched or cyclic aliphatic group of 1 to 18 carbon atoms, substituted alkyl, alkyloxy, aryloxy, alkylthiol, arylthiol, aliphatic amino, aromatic amino, substituted silyloxy, substituted silyl, aryl, substituted aryl, heteroaryl and substituted heteroaryl.

In particular, the heteroaryl is furyl, thienyl, pyrrolyl, pyridyl, quinolyl, indolyl, carbazyl, acridone group, phenothiazinyl or acridinyl.

R₃ is especially preferably halogen, C₆-C₉ aryl or carbazyl.

In the present disclosure, halogen includes fluorine, chlorine, bromium and iodine.

In the present disclosure, C₆-C₉ aryl includes phenyl, tolyl, ethylphenyl or propylphenyl, etc.

For example, when R₃ is fluorine, methyl and phenyl, the structural formulae are as follows:

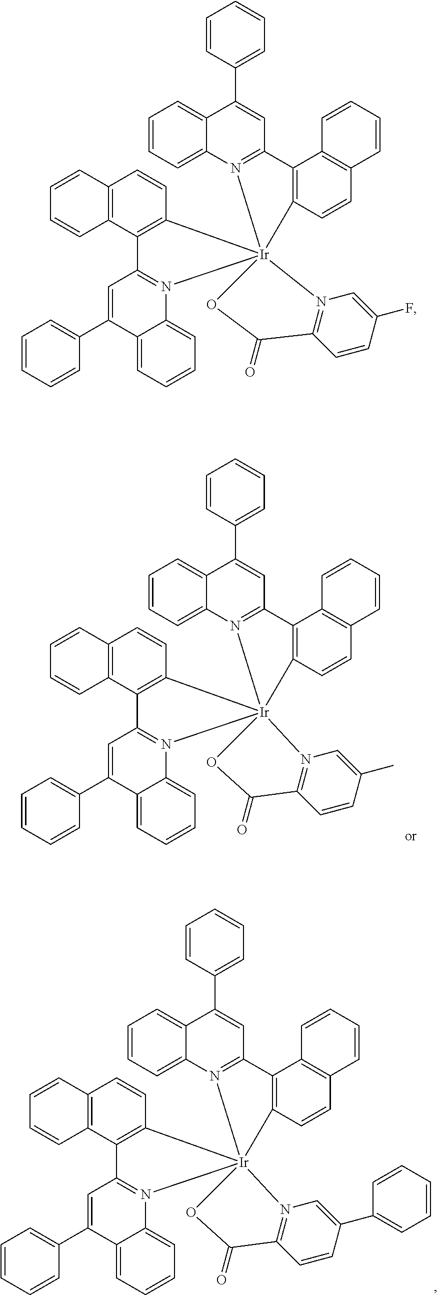

respectively.

In another preferred embodiment, the invention provides a bicyclic iridium complex having the following structural formula:

The bicyclic iridium complex has the following structural formulae: Error! Objects cannot be created from editing field codes. Error! Objects cannot be created from editing field codes.

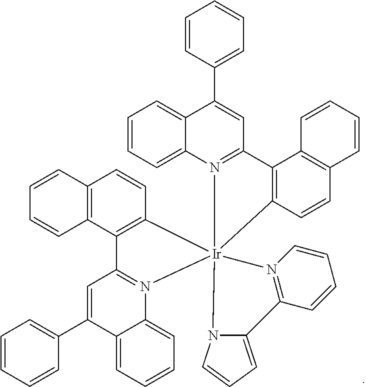

The aforesaid compounds are all encompassed in the invention.

Further, in the aforesaid solution, the bicyclic iridium complex preferably has the molecular formula (NPQ)₂Ir(pic), which has the following structural formula:

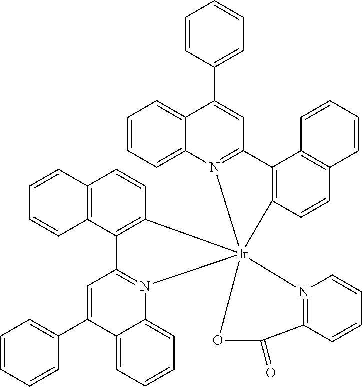

Although organic light emitting has currently been used for all color display, it still has the problems of poor light emitting stability, not high enough light emitting efficiency and low saturation of single color light. In the organic light emitting device, the most important functional layer that determines the light emitting wavelength and light emitting efficiency of the device is the light emitting layer. In order to solve the problems of the existing organic light emitting device of poor light emitting stability, not high enough light emitting efficiency, and low saturation of single color light, the invention further provides an organic light emitting device, whose light emitting layer comprises the aforesaid bicyclic iridium complex.

Polyvinyl carbozole (PVK) is a commonly used blue light emitting electro-optic polymer with wide forbidden band, which has advantages such as good film forming property, high glass temperature, high hole migration rate, and the like, and has the following structural formula:

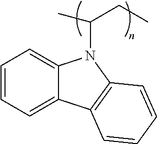

In recent years, PVK is widely used as a matrix for doping with phosphorescent material to prepare a polymeric light-emitting diode. The light emitting layer of the organic light emitting device of the invention can be formed from a mixture of PVK and (NPQ)₂Ir(pic).

2-(4′-t-butylphenyl)-5-(4″-biphenylyl)-1,3,4-oxidiazole (PBD) is an excellent electron transport material and has the following structural formula:

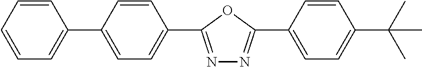 [SMILES: CC(C)(C)c1ccc(-c2nnc(-c3ccc(-c4ccccc4)cc3)o2)cc1]

Further, the light emitting layer can be formed from a mixture of PVK, PBD and (NPQ)₂Ir(pic).

Further, in the aforesaid solution, the weight ratio of (NPQ)₂Ir(pic) to the light emitting layer can be 1%-20%, specifically, it can be 1-10%, such as 1%-8%, preferably 1.5%-5%, and most preferably 2%-4%. The optical performance of the device can be adjusted by changing the ratio of said material in the light emitting layer. The resultant red light emitting device has high saturation, high quantum efficiency, stable performance and has potential application value. The light emitting layer used in the invention comprises two host materials, PVK and PBD, respectively. PBD not only serves as a host material in the light emitting layer, but also serves as an electron transport material. As compared to other red light emitting device, the organic light emitting device has the following advantages: high external quantum efficiency, a high saturation of red light emission, and stable light emitting performance upon the change of electric current.

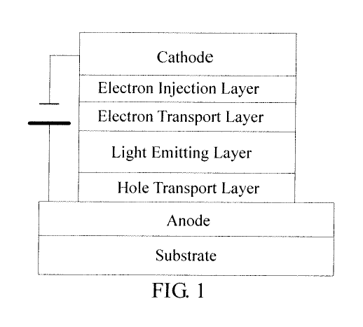

Further, as shown in FIG. 1, the organic light emitting device of the invention comprises:

a substrate;

an anode disposed on the substrate;

a hole transport layer disposed on the anode;

a light emitting layer disposed on the hole transport layer;

an electron transport layer disposed on the light emitting layer;

an electron injection layer disposed on the electron transport layer;

a cathode disposed on the electron injection layer.

Further, in the aforesaid solution, the thickness of the light emitting layer does not exceed 100 nm, such as 40 nm-100 nm, preferably about 70 nm.

According the present invention, a process for preparing the aforesaid bicyclic iridium complex is further provided including the following steps:

Step (1), phosphorus pentoxide is dissolved in m-cresol, to which 1-naphthalen-1-yl-ethylketone and the o-aminobenzaldehyde derivative of Formula (2) are further added for dehydration, resulting in the 2-naphthalen-1-yl quinoline derivative as shown in Formula (3);

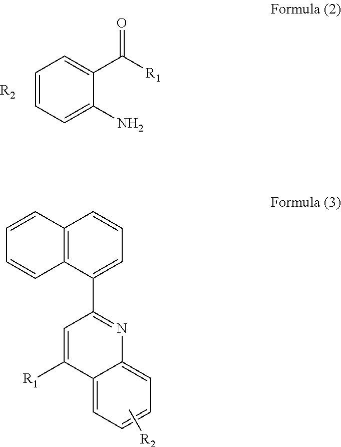

wherein substituents R₁ and R₂ are defined as the same as in Claim 1.

Step (2), IrCl₃.3H₂O is dissolved in water, to which a 2-naphthalen-1-yl quinoline derivative and a first organic solvent are added, followed by agitation in the dark under a N₂ environment, resulting in a bichloro bridge compound of iridium as shown in Formula (4);

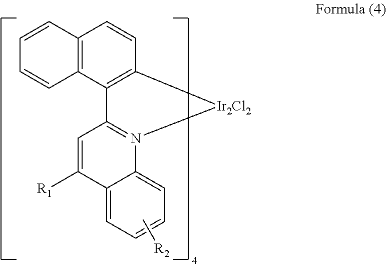

Step (3), the bichloro bridge compound of iridium is dissolved in a second organic solvent, and is agitated with an adjuvant ligand under the action of an alkali, resulting in the bicyclic iridium complex of the present disclosure. wherein the adjuvant ligand is selected from a ligand of N—COOHs, 8-hydroxyquinolines, β-diones and N̂NH. Examples of each type of ligands are as mentioned previously.

For example, available adjuvant ligand may include, but is not limited to: picolinic acids (e.g., 2-picolinic acid), acylketones (such as acetoacetone), 8-hydroxyquinoline or 2-(1-hydrogen-pyrrol-2-yl)-pyridine.

wherein in Step (1), preferably, the ratio of the amounts of phosphorus pentoxide, m-cresol, 1-naphthalen-1-yl-ethylketone and the o-amino benzaldehyde derivative is roughly: 1:10˜80:1:1, and the duration of dehydration is 4-24 h;

In Step (2), preferably, the ratio of the amounts of IrCl₃.3H₂O, the 2-naphthalen-1-yl quinoline derivative and the first organic solution is roughly 1:(2˜5):(50˜300), and the agitation in the dark is conducted at temperature of 50˜200° C. and N₂ environment for 8˜48 h;

In Step (3), preferably, the ratio of the amounts of the dichloro bridge compound of iridium, the second organic solution, the alkali and the adjuvant ligand is roughly 1:(10˜500):(1˜5):(1˜5), and the agitation is conducted with the adjuvant ligand under the action of the alkali at 20˜200° C. for 3˜48 h.

In aforesaid steps, the amount used for some materials is a range, which indicates that the amount used within said range will not have too much effect on the yield of the compound prepared in the step, but if it exceeds this range, the yield of the compound will greatly drop.

Wherein, the first organic solvent is selected from ethylene glycol ethyl ether, glycidyl ether and glycerol;

the second organic solvent is selected from one or more of dichloromethane, ethylene glycol ethyl ether, glycerol and glycidyl ether;

the alkali is selected from potassium carbonate, potassium bicarbonate, sodium carbonate, sodium bicarbonate, sodium hydroxide, potassium hydroxide, triethylamine or pyridine;

According to the invention, a process for preparing an organic light emitting device is provided, which process comprises preparing the light emitting layer of the organic light emitting device using the bicyclic iridium complex as shown in Formula (I).

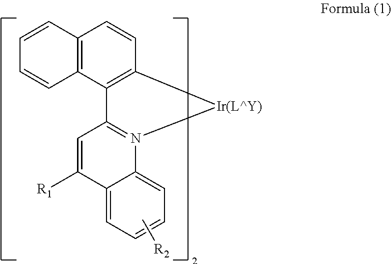

wherein R₁ and R₂ are the same or different substituents.

Further, in the aforesaid solution, the process for preparation further comprises:

conducting vacuum evaporation or spin coating on the hole transport layer with a mixture of the bicyclic iridium complex and PVK, forming the light emitting layer.

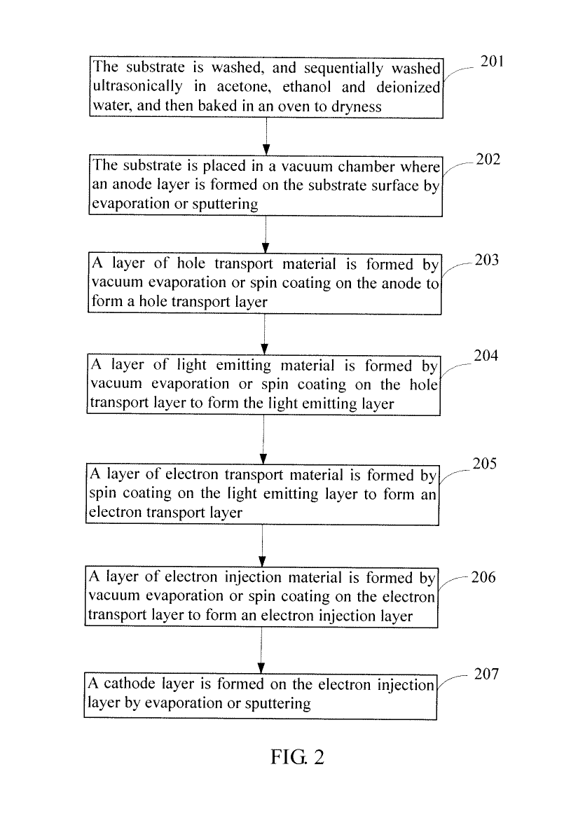

Further, as shown in FIG. 2, the process for preparing the organic light emitting device of the invention comprises:

Step 201: the substrate is washed in which the substrate is sequentially washed ultrasonically in acetone, ethanol and deionized water, and then baked in an oven to dryness, wherein the duration of washing can be 10-20 min;

Step 202: the substrate is placed in a vacuum chamber where an anode layer is formed on the substrate surface by evaporation or sputtering;

Step 203: a layer of hole transport material is formed by vacuum evaporation or spin coating on the anode to form a hole transport layer;

Step 204: a layer of light emitting material is formed by vacuum evaporation or spin coating on the hole transport layer to form a light emitting layer.

In a specific embodiment, the light emitting layer is formed from a light emitting material which is a mixture of PVK and (NPQ)₂Ir(pic). In another preferred embodiment, the light emitting layer is formed from a light emitting material which is a mixture of PVK, PBD and (NPQ)₂Ir(pic).

Step 205: a layer of electron transport material is formed by spin coating on the light emitting layer to form an electron transport layer;

Step 206: a layer of electron injection material is formed by vacuum evaporation or spin coating on the electron transport layer to form an electron injection layer;

Step 207: a cathode layer is formed on the electron injection layer by evaporation or sputtering;

The organic light emitting device prepared in the invention has a light emitting layer whose guest material employs the bicyclic iridium complex, and the host material employs PVK and PBD. The organic light emitting device employing said light emitting layer has a high external quantum efficiency, a high saturation of red light emission, as well as a stable light emitting performance upon change of electric current.

The organic light emitting device and the process for preparing the same of the invention are described in details in reference to specific examples below.

### Compound Example 1 (Synthesis of (NPQ)2Ir(pic))

(1). Synthesis of 2-biphenylyl-4-phenylquinoline

Error! Objects cannot be created from editing field codes.

0.1 g phosphorus pentoxide and 20 ml m-cresol were added into a two-necked flask and reacted at 140□ for 3 hours. Then 0.170 g (1 mmol) 1-naphthalen-1-yl-ethylketone and 0.197 g (1 mmol) 2-amino-benzophenone in 20 ml m-cresol is added, followed by refluxing at 180□ for 6 h, cooling to the room temperature and pouring into 200 ml 10% sodium hydroxide solution. The resultant mixture was extracted with dichloromethane. The organic phase was washed with 200 ml sodium hydroxide aqueous solution three times and spinned into a silica gel column for purification, resulting in a yellow product, which was then re-crystallized with ethanol to yield 2-biphenylyl-4-phenylquinoline as a light yellow crystal.

Yield: 76%.

Melting point: 40° C.

1H NMR (CDCl3, 400 MHz) δ (ppm): 8.32-8.30 (d, 1H), 8.26-8.24 (d, 1H), 8.05-8.03 (d, 1H), 7.97-7.93 (t, 2H), 7.82-7.77 (m, 2H), 7.69 (s, 1H), 7.63-7.48 (m, 9H). GC-MS (m/z): 330.

(2) Synthesis of a Dichloro Bridge Compound of Iridium

Error! Objects cannot be created from editing field codes.

Dichloro Bridge Compound of Iridium

IrCl₃.3H₂O (1 mmol) was added into a three-necked flask which was vacuumed, filled with nitrogen and again vacuum with Schlenk line for three cycles, before the reaction system was protected with nitrogen. 2-biphenylyl-4-phenylquinoline (2.5 mmol), and a mixture of 2-ethoxyethanol and water (with a volume ratio 3:1) were each injected into the reaction system using syringes, followed by agitation and heating the reaction system to 120° C. for a reaction of 16˜24 hours, during which reaction red precipitates were produced. The reaction system was cooled to the room temperature, followed by filtration of precipitates and washing with water and ethanol to yield a yellowish green solid product, that is, the dichloro bridge compound of iridium

(3) Synthesis of (NPQ)₂Ir(pic)

Error! Objects cannot be created from editing field codes.

The dichloro bridge compound of iridium (0.2 mmol) and Na₂CO₃ (1.0 mmol) were added together into a three-necked flask which was vacuumed, filled with nitrogen and again vacuum with Schlenk line for three cycles, before the reaction system was protected with nitrogen. 2-picolinic acid (0.6 mmol) and 2-ethoxyethanol (5 mL) were each filled into the reaction system using syringes, followed by agitation and heating the reaction system to reflux. After 16 hours of reaction, the reaction mixture was cooled to the room temperature and filtered to obtain a red precipitate, which was subsequent purified using column chromatography with DCM/EA (with a volume ratio of 2:1) as the eluent to obtain the red solid complex (NPQ)₂Ir(pic).

Yield: 40%.

1HNMR (CDCl3, 400 MHz) δ (ppm): 8.80-8.78 (d, 2H), 8.69-8.67 (d, 2H), 8.62 (s, 1H), 8.10-8.08 (d, 1H), 7.82-7.72 (m, 6H), 7.66-7.49 (m, 13H), 7.44-7.29 (m, 5H), 7.25-7.16 (m, 3H), 7.10-7.08 (d, 1H), 6.79-6.75 (t, 1H), 6.60-6.58 (d, 1H). EI-MS (m/z): 998([M+Na]+).

### Compound Examples 2, 3 and 4

(1) Synthesis of Dichloro Bridge Compound of Iridium

Dichloro bridge compound of iridium was obtained by repeating Step (1) and (2) in Compound Example 1.

(2) Synthesis of Compound 2

Error! Objects cannot be created from editing field codes. Error! Objects cannot be created

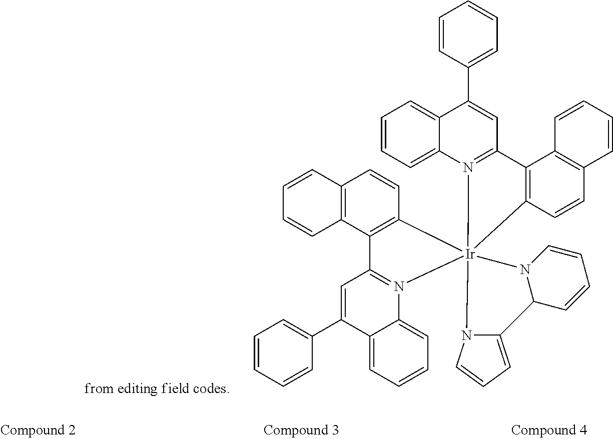

The dichloro bridge compounds of iridium (0.2 mmol) and Na₂CO₃ (1.0 mmol) were added together into a three-necked flask which was vacuumed, filled with nitrogen and again vacuum with Schlenk line for three cycles, before the reaction system was protected with nitrogen. Acetoacetone (0.6 mmol) and 2-ethoxyethanol (5 mL) were each filled into the reaction system using syringes, followed by agitation and heating the reaction system to reflux. After 16 hours of reaction, the reaction mixture was cooled to the room temperature and filtered to obtain a red precipitate, which was subsequent purified using column chromatography with DCM/EA (with a volume ratio of 2:1) as the eluent to obtain the red solid complex, that is, Compound 2.

When repeating the Step (2) above, the acetoacetone used in that step was changed to 8-hydroxyquinoline or 2-(1-hydrogen-pyrrol-2-yl)-pyridine to yield Compound 3 and Compound 4, respectively.

The organic light emitting device will be prepared based on Compound Example 1 below.

### Example 1

In this example, the organic light emitting device has the following structure: the anode employs indium tin oxide, the hole transport layer employs PEDOT/PSS (poly(3,4-ethylenedioxythiophene) doped with polystyrene sulfonic acid), and has a thickness of 40 nm; the thickness of the light emitting layer is 70 nm; the electron transport layer employs TPBI (1,3,5-tris(1-phenyl-1H-benzimidazol-2-yl)benzene) and has a thickness of 30 nm; the electron injection layer employs cesium fluoride (CsF), and has a thickness of 1.5 nm; the anode employs aluminum (Al) and has a thickness of 120 nm. In the light emitting layer, the weight ratio of PVK, PBD and (NPQ)₂Ir(pic) is 69:30:1.

The process for preparing the organic light emitting device of the present example comprised the following steps:

A: An indium tin oxide (ITO) electrically conductive glass substrate was washed in acetone, a detergent, deionized water and isopropanol solution, and then baked in an oven to dryness. The cleaned substrate was subjected to an oxygen plasma treatment to increase the work function of ITO. The organic contaminant remained on the ITO surface was further cleaned and the surface contact angle of the substrate was improved.

B: A layer of PEDOT/PSS film with a thickness of 40 nm was spin coated on the substrate after step A which increased the Fermi level of ITO to −5.2˜−5.3 eV, which greatly reduced the potential barrier for holes to be injected from the anode.

C: The substrate spin coated with PEDOT/PSS was dried for 8 h in a vacuum oven at 80° C. for 8 h and then transferred to a glove box filled with nitrogen to form the light emitting layer. The PVK, PBD and (NPQ)₂Ir(pic) to be used were dissolved in chlorobenzene and then the solution was spin coated on the substrate with a thickness of 70 nm. The weight ratio of PVK:PBD:(NPQ)₂Ir(pic)=69:30:1;

D: In a high vacuum of less than 3×10⁻⁴ Pa, CsF of about 1.5 mm thickness was coated by evaporation as the electron injection layer and Al of about 120 nm thickness was coated by evaporation as the cathode.

The spectral peaks of the organic light emitting device of the example were composed of two parts. One part was the emission of the host material (peak at 436 nm) and the other part was the emission of the guest material (peak at 638 nm). This peak value had a certain degree of red shift as compared to the light emitting spectrum which was caused by the nature of light emitting. In the example, the doping concentration of the guest material was about 1%. The emission of the host material was somewhat significant, this is because the concentration of the guest material in the organic light emitting device was too low to completely absorb the energy conveyed from the host material, thereby allowing the host material to participate in the light emitting and consume some of the exciton energy.

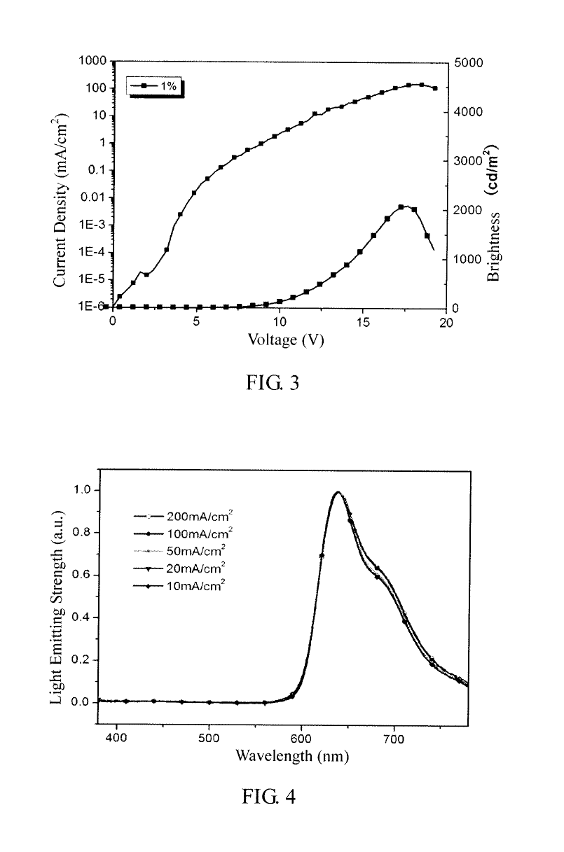

FIG. 3 is the current density-voltage-brightness plot of the organic light emitting device of the example. From FIG. 3, it can be seen that the current density of the organic light emitting device increases continuously with the increase of the external voltage. With the continuous increase of the voltage, the brightness of the organic light emitting device first increases before decreases again. The organic light emitting device has a maximal brightness of 2214 cd/m², a chromaticity co-ordinate of (0.6513, 0.2796) (the chromaticity system being [CIE 1931]), an initial voltage of 4.9V, and a maximal external quantum efficiency of 12.38%.

### Example 2

In this example, the organic light emitting device has the following structure: the anode employs ITO, the hole transport layer employs PEDOT/PSS, and has a thickness of 40 nm; the thickness of the light emitting layer is 70 nm; the electron transport layer employs TPBI and has a thickness of 30 nm; the elctron injection layer employs CsF, and has a thickness of 1.5 nm; the anode employs Al and has a thickness of 120 nm. In the light emitting layer, the weight ratio of PVK, PBD and (NPQ)₂Ir(pic) is 69:29:2.

The process for preparing the organic light emitting device of the present example comprised the following steps:

A: An indium tin oxide (ITO) electrically conductive glass substrate was washed in acetone, a detergent, deionized water and isopropanol solution, and then baked in an oven to dryness. The cleaned substrate was subjected to an oxygen plasma treatment to increase the work function of ITO. The organic contaminant remained on the ITO surface was further cleaned and the surface contact angle of the substrate was improved.

B: A layer of PEDOT/PSS film with a thickness of 40 nm was spin coated on the substrate after step A which increased the Fermi level of ITO to −5.2˜−5.3 eV, which greatly reduced the potential barrier for holes to be injected from the anode.

C: The substrate spin coated with PEDOT/PSS was dried for 8 h in a vacuum oven at 80° C. for 8 h and then transferred to a glove box filled with nitrogen to form the light emitting layer. The PVK, PBD and (NPQ)₂Ir(pic) to be used were dissolved in chlorobenzene and then the solution was spin coated on the substrate with a thickness of 70 nm. The weight ratio of PVK:PBD:(NPQ)₂Ir(pic)=69:29:2;

D: In a high vacuum of less than 3×10⁻⁴ Pa, CsF of about 1.5 mm thickness was coated by evaporation as the electron injection layer and Al of about 120 nm thickness was coated by evaporation as the cathode.

As compared to Example 1, in Example 2, with the increase of the (NPQ)₂Ir(pic) doping concentration, the emission peak of the host material gradually decreases. When the doping concentration of the guest material increases from 1% to 2%, the reduction of the emission peak of the host material is very significant. FIG. 4 is the light emitting spectrum of the organic light emitting device of the example under different current density. From FIG. 4, it can be seen that the change in current density does not have a huge impact on the light emitting of the organic light emitting device, indicating that the organic light emitting device of the example has good stability under different current density. The organic light emitting device has a maximal brightness of 3034 cd/m², a chromaticity co-ordinate of (0.6796, 0.3005) (the chromaticity system being [CIE 1931]), an initial voltage of 5.5V, and a maximal external quantum efficiency of 13.96%. As compared to Example 1, the organic light emitting device of Example 2 has a higher saturation of red color light and a higher maximal external quantum efficiency, but the increase of the concentration of the iridium complex causes the increase of the initial voltage.

### Example 3

In this example, the organic light emitting device has the following structure: the anode employs ITO, the hole transport layer employs PEDOT/PSS, and has a thickness of 40 nm; the thickness of the light emitting layer is 70 nm; the electron transport layer employs TPBI and has a thickness of 30 nm; the elctron injection layer employs CsF, and has a thickness of 1.5 nm; the anode employs Al and has a thickness of 120 nm. In the light emitting layer, the weight ratio of PVK, PBD and (NPQ)2Ir(pic) is 68:28:4.

The process for preparing the organic light emitting device of the present example comprised the following steps:

A: An indium tin oxide (ITO) electrically conductive glass substrate was washed in acetone, a detergent, deionized water and isopropanol solution, and then baked in an oven to dryness. The cleaned substrate was subjected to an oxygen plasma treatment to increase the work function of ITO. The organic contaminant remained on the ITO surface was further cleaned and the surface contact angle of the substrate was improved.

B: A layer of PEDOT/PSS film with a thickness of 40 nm was spin coated on the substrate after step A which increased the Fermi level of ITO to −5.2.˜−5.3 eV, which greatly reduced the potential barrier for holes to be injected from the anode.

C: The substrate spin coated with PEDOT/PSS was dried for 8 h in a vacuum oven at 80° C. for 8 h and then transferred to a glove box filled with nitrogen to form the light emitting layer. The PVK, PBD and (NPQ)₂Ir(pic) to be used were dissolved in chlorobenzene and then the solution was spin coated on the substrate with a thickness of 70 nm. The weight ratio of PVK:PBD:(NPQ)₂Ir(pic)=68:28:4;

D: In a high vacuum of less than 3×10⁻⁴ Pa, CsF of about 1.5 mm thickness was coated by evaporation as the electron injection layer and Al of about 120 nm thickness was coated by evaporation as the cathode.

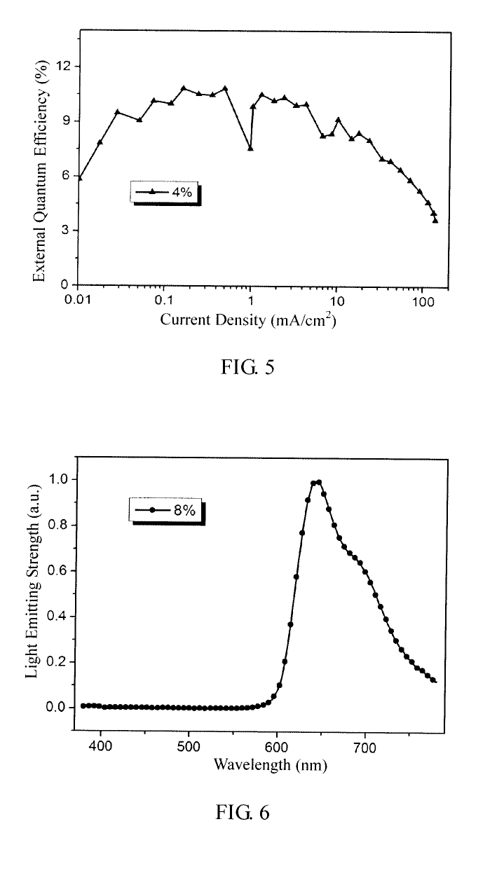

As compared to Example 1 and Example 2, when the doping concentration of (NPQ)₂Ir(pic) increases to 4%, the emission of the host material totally disappears, leaving only the red light emission of the iridium complex (NPQ)₂Ir(pic). This is because with the increase of the doping concentration of (NPQ)₂Ir(pic), the light emitting spots in the light emitting layer increase, the probability of the absorption of the exciton energy of the host material also increases, and the remaining exciton energy decreases relatively. FIG. 5 is the current density-external quantum efficiency plot of the organic light emitting device of the example. From Example 5, it can be seen that the external quantum efficiency of the organic light emitting device first increases and then decreases with the increase of the current density. It is a common phenomenon that with the increase of the current density, the efficiency of the phosphorescent device rapidly decreases, which is due to the quenching of triplet excitons. Quenching includes triplet-triplet quenching, triplet-exciton quenching and field quenching, the former two usually existing in a phosphorescent device. The organic light emitting device has a maximal brightness of 2859 cd/m², a chromaticity co-ordinate of (0.6854, 0.3004) (the chromaticity system being [CIE 1931]), an initial voltage of 7.3V, and a maximal external quantum efficiency of 11.36%. As compared to Example 1 and Example 2, the organic light emitting device obtained in Example 3 has the highest color saturation.

### Example 4

In this example, the organic light emitting device has the following structure: the anode employs ITO, the hole transport layer employs PEDOT/PSS, and has a thickness of 40 nm; the thickness of the light emitting layer is 70 nm; the electron transport layer employs TPBI and has a thickness of 30 nm; the elctron injection layer employs CsF, and has a thickness of 1.5 nm; the anode employs Al and has a thickness of 120 nm. In the light emitting layer, the weight ratio of PVK, PBD and (NPQ)₂Ir(pic) is 66:26:8.

The process for preparing the organic light emitting device of the present example comprised the following steps:

A: An indium tin oxide (ITO) electrically conductive glass substrate was washed in acetone, a detergent, deionized water and isopropanol solution, and then baked in an oven to dryness. The cleaned substrate was subjected to an oxygen plasma treatment to increase the work function of ITO. The organic contaminant remained on the ITO surface was further cleaned and the surface contact angle of the substrate was improved.

B: A layer of PEDOT/PSS film with a thickness of 40 nm was spin coated on the substrate after step A which increased the Fermi level of ITO to −5.2˜−5.3 eV, which greatly reduced the potential barrier for holes to be injected from the anode.

C: The substrate spin coated with PEDOT/PSS was dried for 8 h in a vacuum oven at 80° C. for 8 h and then transferred to a glove box filled with nitrogen to form the light emitting layer. The PVK, PBD and (NPQ)₂Ir(pic) to be used were dissolved in chlorobenzene and then the solution was spin coated on the substrate with a thickness of 70 nm. The weight ratio of PVK:PBD:(NPQ)₂Ir(pic)=66:26:8;

D: In a high vacuum of less than 3×10⁻⁴ Pa, CsF of about 1.5 mm thickness was coated by evaporation as the electron injection layer and Al of about 120 nm thickness was coated by evaporation as the cathode.

FIG. 6 is the light emitting spectrum of the organic light emitting device of the example. From FIG. 6, it can be seen that the various properties of the organic light emitting device obtained in Example 4 are poorer as compared to Example 1, 2 and 3. This is because with the increase of the concentration of the guest material, the iridium complex, the organic light emitting device starts to drop off, causing the decrease of the performance of the organic light emitting device and the increase of the initial voltage. The organic light emitting device has a maximal brightness of 2000 cd/m², a chromaticity co-ordinate of (0.6909, 0.3006) (the chromaticity system being [CIE 1931]), an initial voltage of 9.5V, and a maximal external quantum efficiency of 9.67%.

In the invention, the light emitting layer of the organic light emitting device comprises two host materials, PVK and PPD, respectively. PBD serves not only as the host material in the light emitting layer, but also as an electron transport material. (NPQ)₂Ir(pic) is employed as the gust material. The red light emitting device using these materials for the light emitting layer has a high external quantum efficiency, stable performance, and a high saturation of red light emission, allowing great potential of application for said organic light emitting device in the all color display field.

The aforesaid are merely exemplary embodiments of the invention, rather than used to limit the scope of the invention, which is determined by the appended claims.

1. A bicyclic iridium complex having a structure as shown in Formula (1): 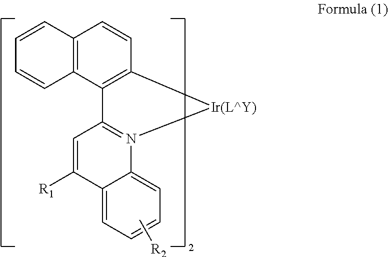
wherein R₁ and R₂ are the same or different substituents, and are each independently selected from one of hydrogen, halogen, cyano, nitro, acyl, linear, branched or cyclic aliphatic group of 1 to 18 carbon atoms, substituted alkyl, alkyloxy, aryloxy, alkylthiol, arylthiol, aliphatic amino, aromatic amino, substituted silyloxy, substituted silyl, aryl, substituted aryl, heteroaryl and substituted heteroaryl;
L̂Y is selected from a ligand of N—COOH, 8-hydroxyquinolines, β-diones and N̂NH.

2. The bicyclic iridium complex of claim 1, wherein R₁ and R₂ are each independently selected from hydrogen, halogen, cyano, nitro, linear or branched alkyl of 1 to 5 carbon atoms, and phenyl, furyl, thienyl, pyrrolyl, pyridyl, quinolyl, indolyl, carbazyl, acridone group, phenothiazinyl or acridinyl substituted by linear or branched alkyl of 1 to 5 carbon atoms.

3. The bicyclic iridium complex of claim 1, wherein the bicyclic iridium complex has a structural formula as shown below ((NPQ)₂Ir(pic)):

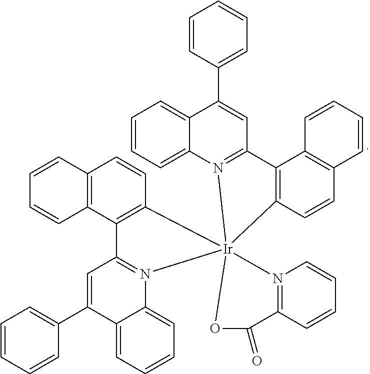

4. The bicyclic iridium complex of claim 1, wherein the bicyclic iridium complex has a structural formula as shown below:

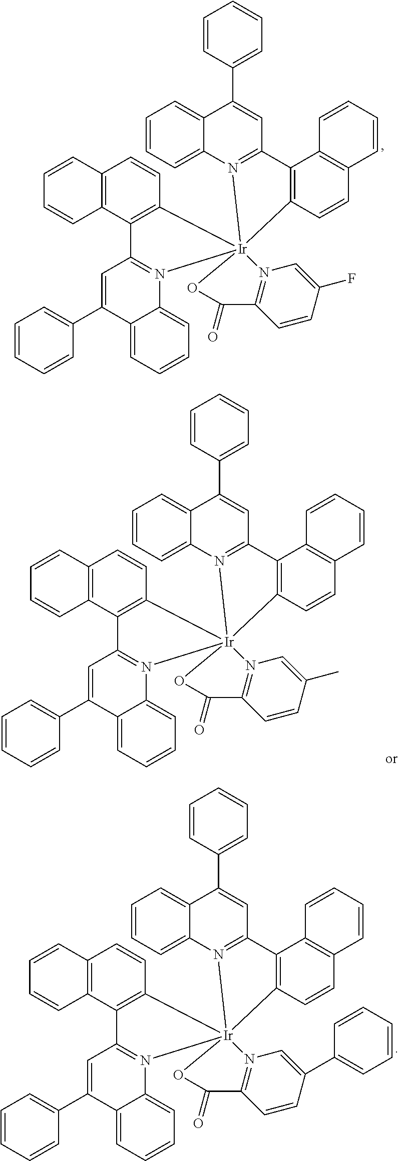

5. The bicyclic iridium complex of claim 1, wherein the bicyclic iridium complex has the structural formula as shown below:

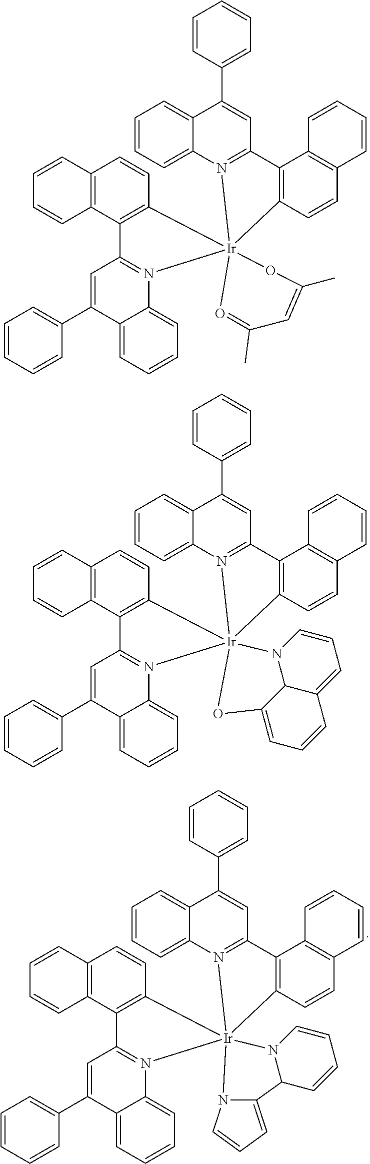

6. An organic light emitting device, wherein the light emitting layer of the organic light emitting device comprises the bicyclic iridium complex of claim 1.

7. The organic light emitting device of claim 6, wherein the light emitting layer is formed from a mixture of polyvinyl carbozole (PVK) and (NPQ)₂Ir(pic).

8. The organic light emitting device of claim 6, wherein the light emitting layer includes a host material and a guest material, wherein the host material comprises PVK and 2-(4′-t-butylphenyl)-5-(4″-biphenylyl)-1,3,4-oxidiazole (PBD), and the guest material comprises (NPQ)₂Ir(pic).

9. The organic light emitting device of claim 8, wherein the weight ratio of (NPQ)₂Ir(pic) to the light emitting layer is 1%-8%, preferably 1.5%-7%.

10. The organic light emitting device of claim 9, wherein the weight ratio of (NPQ)₂Ir(pic) to the light emitting layer is 1.5%-5%, preferably 2%-4%.

11. The organic light emitting device of claim 6, wherein the organic light emitting device includes:
a substrate;
an anode disposed on the substrate;
a hole transport layer disposed on the anode;
a light emitting layer disposed on the hole transport layer;
an electron transport layer disposed on the light emitting layer;
an electron injection layer disposed on the electron transport layer; and
a cathode disposed on the electron injection layer.

12. The organic light emitting device of claim 6, wherein the thickness of the light emitting layer does not exceed 100 nm, preferably 40 nm˜100 nm.

13. A process for preparing the bicyclic iridium complex of claim 1, comprising:
Step (1), phosphorus pentoxide is dissolved in m-cresol, to which 1-naphthalen-1-yl-ethylketone and the o-aminobenzaldehyde derivative of Formula (2) are further added for dehydration, resulting in the 2-naphthalen-1-yl quinoline derivative as shown in Formula (3); 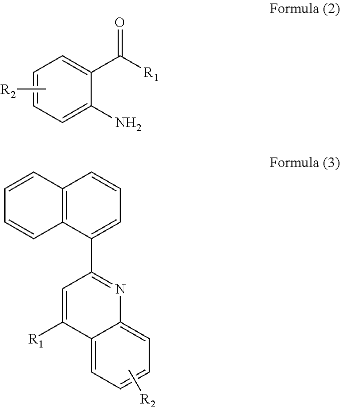
wherein substituents R₁ and R₂ are defined as the same as in claim 1.
Step (2), IrCl₃.3H₂O is dissolved in water, to which a 2-naphthalen-1-yl quinoline derivative as shown in Formula (3) and a first organic solvent are added, followed by agitation in the dark under a N₂ environment, resulting in a bichloro bridge compound of iridium as shown in Formula (4); 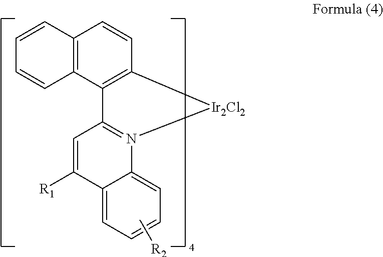
Step (3), the bichloro bridge compound of iridium is dissolved in a second organic solvent, and is agitated with an adjuvant ligand under the action of an alkali, resulting in the bicyclic iridium complex.

14. The process for preparing the bicyclic iridium complex of claim 13, wherein,
in Step (1), the ratio of the amounts of phosphorus pentoxide, m-cresol, 1-naphthalen-1-yl-ethylketone and the o-amino benzaldehyde derivative is roughly 1:(10˜80):1:1, and the duration of dehydration is 4-24 h;
in Step (2), the ratio of the amounts of IrCl₃.3H₂O, the 2-naphthalen-1-yl quinoline derivative and the first organic solution is roughly 1:(2˜5):(50˜300), and the agitation in the dark is conducted at a temperature of 50˜200° C. and N₂ environment for 8˜48 h;
in Step (3), dichloro bridge compound of iridium, the second organic solution, the alkali and the adjuvant ligand are used in a rough ratio of 1:10˜500:1˜5:1˜5, and the agitation is conducted with the adjuvant ligand under the action of the alkali at 20˜200° C. for 3˜48 h.

15. The process for preparing the bicyclic iridium complex of claim 13, wherein,
the first organic solvent is selected from ethylene glycol ethyl ether, glycidyl ether and glycerol;
the second organic solvent is selected from one or more of dichloromethane, ethylene glycol ethyl ether, glycerol and glycidyl ether;
the alkali is selected from potassium carbonate, potassium bicarbonate, sodium carbonate, sodium bicarbonate, sodium hydroxide, potassium hydroxide, triethylamine or pyridine; and
the adjuvant ligand is a ligand of N—COOH, 8-hydroxyquinolines, β-diones and N̂NH.

16. A process for preparing an organic light emitting device, wherein the process comprises preparing the light emitting layer of the organic light emitting device using the bicyclic iridium complex of claim 1.

17. The process for preparing the organic light emitting device of claim 16, further comprising:
conducting vacuum evaporation or spin coating on the hole transport layer with a mixture of the bicyclic iridium complex and PVK, forming the light emitting layer.
